(19) United States
(12) Patent Application Publication
(10) Pub. No.: US 2007/0048991 A1
(43) Pub. Date: Mar. 1, 2007

(54) Copper interconnect structures and fabrication method thereof

(75) Inventors: Chien-Hsueh Shih, Taipei (TW); Ming-Hsing Tsai, Chu-Pei City (TW); Hung-Wen Su, Jhubei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/209,891

(22) Filed: Aug. 23, 2005

(51) Int. Cl. H01L 21/44

(52) U.S. Cl. 438/597

(57) ABSTRACT

Copper interconnect structures for interconnection. The interconnect structure has a copper recess in a damascene structure with copper filled in a via/trench of a dielectric layer. Furthermore, the interconnect structure can also have a metal cap filled the copper recess.

### BACKGROUND

The invention relates in general to copper interconnect structure, and more particularly to a copper recess formed in a damascene structure.

Chip manufacturers continually attempt to improve manufacturing processes to achieve higher chip operating speed. As semiconductor process technologies evolve, operating speed has been hindered by an RC delay of a multilevel interconnect. The RC delay is a multiplication of resistance and capacitance of the multilevel interconnect. Copper is among the best choices for use in multilevel interconnect due to its low resistance.

In a conventional copper interconnect process, a dielectric stop layer, such as nitride layer, is deposited after copper CMP (chemical mechanical polishing). The poor interface between copper and the stop layer is a major obstacle to reliability. To improve the interface between copper and the stop layer, metal capping such as W, Co, CoWP and CoWB have been proposed. Such metal capping is often formed by selective growth, thus, it is not easy to control and results in lateral growth of metal capping. The leakage current due to lateral growth of metal capping is of great concern.

### SUMMARY

Embodiments of the invention provide an interconnect structure. The interconnect structure comprises a damascene structure and a copper conductor in the damascene structure. The damascene structure comprises a via and/or a trench in a dielectric layer. A top surface of the conductor is lower than a top surface of the dielectric layer and a conductor recess is thus formed.

Embodiments of the invention additionally provide another interconnect structure. The interconnect structure comprises a conductor recess in a damascene structure and a conductive cap on the conductor recess without overfilling the conductor recess.

Embodiments of the invention further provide a method for fabricating an interconnect structure. A via/trench is formed in a dielectric layer. The via/trench is subsequently overfilled with copper conductor. Thereafter, a copper removal process is performed to make a top surface of the copper conductor lower than a top surface of the dielectric layer. Thus, a copper recess is formed.

Since the interconnect structure comprises a copper recess, the selective growth of a metal cap in the copper recess can be well controlled. No lateral growth of the metal cap results and thus no short or leakage issues occur.

### BRIEF DESCRIPTION OF THE DRAWINGS

Embodiments of the invention will become more fully understood from the detailed description given herein below and the accompanying drawings, given by way of illustration only and thus not intended to be limitative of the present invention.

FIGS. 1A to 1H are cross-sections showing a method for forming an interconnect structure according to an embodiment of the invention.

### DETAILED DESCRIPTION

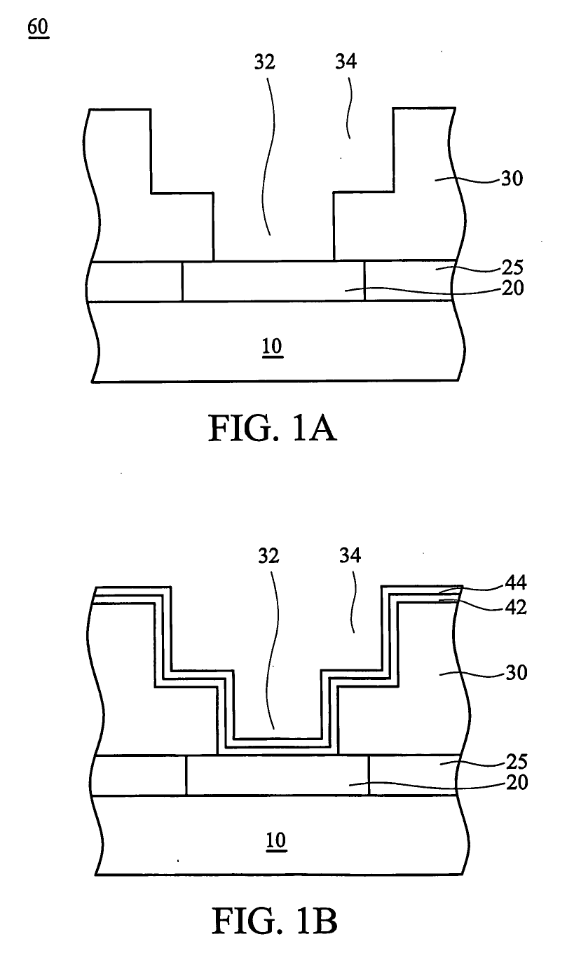

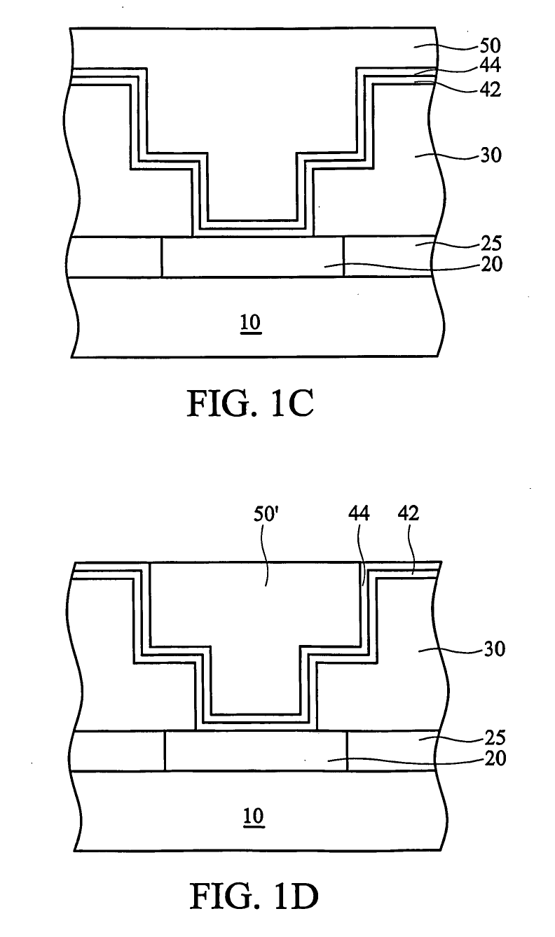

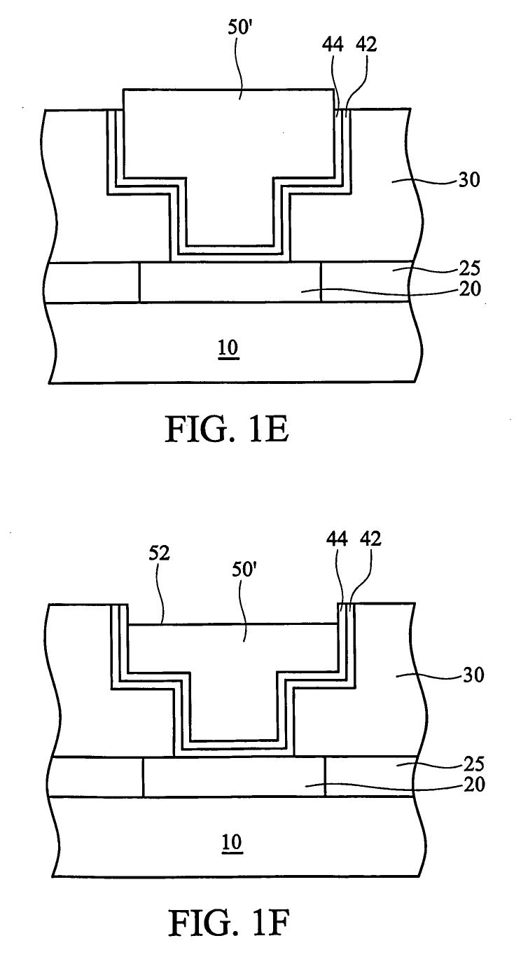

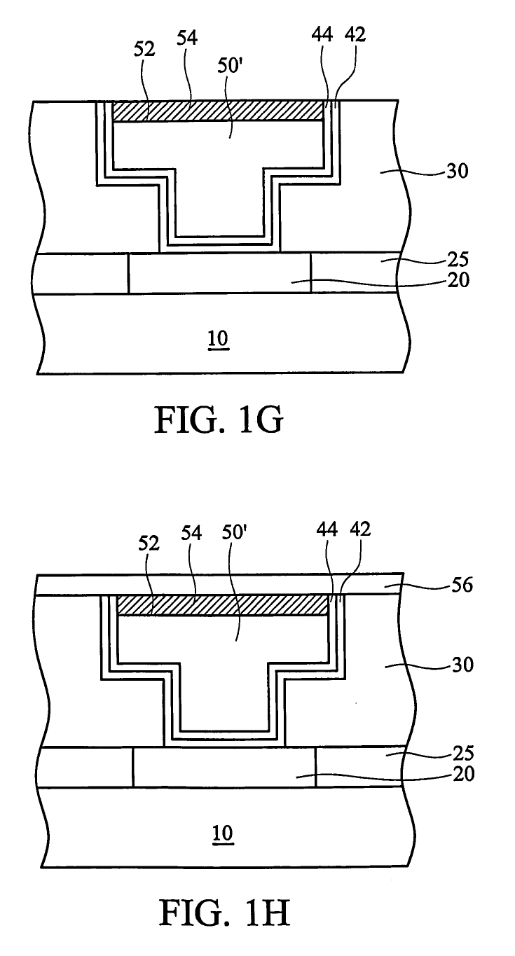

As shown in FIG. 1A, a semiconductor substrate 10 is provided. A metal interconnect 20 patterned within an insulating layer 25, i.e., silicon oxide, is also shown in the figure. Additionally, a dielectric layer 30 is deposited and patterned with a via portion 32 and a trench portion 34. The dual damascene structure 60, including a via portion 32 and a trench portion 34 is thus formed. Although a dual damascene structure is illustrated in FIGS. 1A-1H, other types of interconnect features are also typically metallized using this technique.

As shown in FIG. 1B, a conductive barrier layer 42, preferably including tantalum (Ta) or tantalum nitride (TaN), is deposited over the top surface of the dielectric layer 30, and lining the surfaces of the via portion 32 and the trench portion 34. A seed layer 44, e.g. a copper seed layer, is then deposited on the conductive barrier layer 42 conformally, as shown in FIG. 1B.

As shown in FIG. 1C, the via/trench is overfilled with conductor 50, e.g. copper or copper alloy, by a plating process such as electroless plating or electroplating. As a result, the copper conductor 50 connects electrically to the underlying metal interconnect 20 through the conductive barrier layer 42.

Subsequently, a chemical mechanical polishing (CMP) process is performed to remove part of copper conductor 50 and smooth the top surface so that the remainder of the copper conductor 50′ is substantially coplanar with the surface of the conductive barrier layer 42 (or the seed layer 44 if one exists) on the dielectric layer 30, as shown in FIG. 1D. Thereafter, the seed layer 44 and the conductive barrier layer 42 on the dielectric layer 30 are removed by an etching or another chemical mechanical polishing process, as shown in FIG. 1E. Thus, the top surface of the copper conductor 50′ is slightly higher than the top surface of the dielectric layer 30.

As shown in FIG. 1F, a recess 52 of the conductor 50′ with a depth of 20 Å to 200 Å is formed. The copper recess 52 can be formed by a CMP process. The CMP process is preferably performed with an oxidation agent of hydrogen peroxide(H₂O₂), nitric acid, hypochlorous acid, chromic acid, ammonia, ammonium salt, and a slurry of polishing agent such as alumina(Al₂O₃), and deionized water(DI H₂O) plus BTA(BenzoTriAzole).

The conductor recess 52 can also be formed by a clean process performed after removal of the conductive barrier layer on the dielectric layer 30. The clean process is performed in an acid environment, wherein the acid comprises nitric acid, hypochlorous acid, chromic acid or the like.

Furthermore, as shown in FIG. 1G, a conductive cap 54 is formed to fill the conductor recess 52. Typically, the conductive cap 54 is formed by selective growth so that the conductive material is only formed on the surface of the copper conductor 50′ and within the recess. In a preferred embodiment, the surface of the conductive cap 54 is substantially the same as the surrounded dielectric layer 30. Preferably, the surface of the conductive cap layer 54 is not over the surface of the surround dielectric layer 30. The conductive cap 54 can be any proper conductive material such as a tungsten layer formed by CVD. The preferred conductive cap 54 is cobalt-comprising cap. The cobalt-comprising cap can be metal cobalt(Co), cobalt tungsten(CoW), cobalt tungsten phosphide(CoWP) or cobalt tungsten boride(CoWB). If there is no clean process after removal of the conductive barrier layer on the dielectric layer or additional CMP process to form the copper recess 52, the copper recess 52 can also be formed during a pre-cap clean process before formation of the conductive cap 54. The pre-cap clean process is performed in an acid environment, wherein the acid comprises nitric acid, hypochlorous acid, chromic acid or the like.

Another embodiment of the invention provides an interconnect structure. As shown in FIG. 1F, the interconnect structure comprises a copper recess 52 in a damascene structure with copper conductor 50′ filled in the via/trench of a dielectric layer 30. The preferred depth of the copper recess is about 20 Å to 200 Å.

Furthermore, another embodiment of an interconnect structure according to the invention, as shown in FIG. 1G, also comprises a cap 54 formed on the copper conductor 50′. The cap 54 can be any proper conductive material such as a tungsten layer formed by CVD. Preferably, the conductive cap 54 comprises cobalt, e.g. metal cobalt(Co), cobalt tungsten(CoW), cobalt tungsten phosphide(CoWP), cobalt tungsten boride(CoWB) or a combination thereof.

Since the structure of copper connection comprises a copper recess, the selective growth of a conductive cap on the copper recess can be well controlled. No lateral growth of the conductive cap results and thus no short or leakage issues occur. In a preferred embodiment, an etch stop layer 56 can be formed covering the conductive cap 54 and the dielectric layer 30, as shown in FIG. 1H. The cobalt-comprising cap 54 also improves the interface between the copper conductor 50′ and the above etch stop layer 56.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An interconnect structure, comprising:
a damascene structure comprising a via and/or a trench in a dielectric layer;
a conductor filled the via and/or trench, wherein a top surface of the conductor is lower than a top surface of the dielectric layer; and
a cobalt-comprising cap on the conductor.

2. The interconnect structure as claimed in claim 1, wherein a distance between the top surfaces of the conductor and the dielectric layer is about 20 Å to 200 Å.

3. The interconnect structure as claimed in claim 1, wherein a surface of the cobalt-comprising cap on the conductor is not over the surface of the dielectric layer.

4. The interconnect structure as claimed in claim 3, wherein a top surface of the cap layer is substantially the same as the top surface of the dielectric layer.

5. The interconnect structure as claimed in claim 3, wherein the cobalt-comprising cap comprises metal cobalt (Co), cobalt tungsten(CoW), cobalt tungsten phosphide (CoWP) or cobalt tungsten boride(CoWB).

6. The interconnect structure as claimed in claim 1, further comprising a conductive barrier layer between the conductor and the dielectric layer.

7. The interconnect structure as claimed in claim 6, further comprising a seed layer between the conductive barrier layer and the conductor.

8. The interconnect structure as claimed in claim 1, wherein the conductor comprises copper or copper alloy.

9. The interconnect structure as claimed in claim 1, further comprising an etch stop layer overlying the cobalt-comprising cap and the dielectric layer.

10. A method for fabricating an interconnect structure, the method comprising:
forming a damascene structure in a dielectric layer;
filling the damascene structure with a conductive material as a conductor;
recessing a surface of the conductor to be lower than a top surface of the dielectric layer; and
forming a cobalt-comprising cap on the recessed conductor.

11. The method as claimed in claim 10, wherein the conductor is recessed by a CMP process.

12. The method as claimed in claim 10, wherein the CMP process is performed with an oxidation agent of hydrogen peroxide(H₂O₂), nitric acid, hypochlorous acid, chromic acid, ammonia, ammonium salt, and a slurry of polishing agent.

13. The method as claimed in claim 10, further comprising:
forming a conductive barrier layer lining the damascene structure before filing the conductive material;
performing a chemical mechanical polishing process to make the top surface of the conductor substantially coplanar with a top surface of the conductive barrier layer on the dielectric layer; and
removing the conductive barrier layer on the dielectric layer before recessing the surface of the conductor.

14. The method as claimed in claim 13, wherein the conductor is recessed by a clean process performed after removal of the conductive barrier layer on the dielectric layer.

15. The method as claimed in claim 14, wherein the clean process is performed in an acid environment and the acid comprises nitric acid, hypochlorous acid, or chromic acid.

16. The method as claimed in claim 10, wherein the cobalt-comprising cap is formed on the recessed conductor without overfilling the recessed conductor.

17. The method as claimed in claim 10, wherein the cobalt-comprising cap comprises metal cobalt(Co), cobalt tungsten(CoW), cobalt tungsten phosphide(CoWP) or cobalt tungsten boride(CoWB).

18. The method as claimed in claim 10, wherein cobalt-comprising cap is formed by selective growth within the recessed conductor.

19. The method as claimed in claim 10, wherein the conductor is recessed by a clean process which is performed before formation of the cobalt-comprising cap.

20. The method as claimed in claim 19, wherein the clean process is performed in an acid environment and the acid comprises nitric acid, hypochlorous acid, or chromic acid.

21. The method as claimed in claim 10, further comprising forming an etch stop layer covering the cobalt-comprising cap and the dielectric layer.

22. A method for fabricating an interconnect structure, the method comprising:
forming a damascene structure in a dielectric layer;
forming a conductive barrier layer lining the damascene structure;
filling the damascene structure with a conductive material as a conductor on the conductive barrier layer;
removing the conductive barrier layer on the dielectric layer;
recessing a surface of the conductor to be lower than a top surface of the dielectric layer; and
forming a conductive cap on the recessed conductor.

23. The method as claimed in claim 22, wherein the conductor is recessed by a CMP process.

24. The method as claimed in claim 22, wherein the conductor is recessed by a clean process performed after removal of the conductive barrier layer on the dielectric layer.

25. The method as claimed in claim 24, wherein the clean process is performed in an acid environment and the acid comprises nitric acid, hypochlorous acid, or chromic acid.

26. The method as claimed in claim 22, wherein the conductive cap is formed on the recessed conductor without overfilling the recessed conductor.

27. The method as claimed in claim 22, wherein the conductive cap comprises tungsten(W), cobalt(Co), cobalt tungsten(CoW), cobalt tungsten phosphide(CoWP) or cobalt tungsten boride(CoWB).

28. The method as claimed in claim 27, wherein conductive cap is formed by selective growth.

29. The method as claimed in claim 22, wherein the conductor is recessed by a clean process which is performed before formation of the conductive cap.

30. The method as claimed in claim 29, wherein the clean process is performed in an acid environment and the acid comprises nitric acid, hypochlorous acid, or chromic acid.

31. The method as claimed in claim 22 further comprising forming an etch stop layer covering the conductive cap and the dielectric layer.
